(19) United States
(12) Patent Application Publication
(10) Pub. No.: US 2011/0236675 A1
(43) Pub. Date: Sep. 29, 2011

(54) METHOD OF FORMING FILM

(75) Inventors: Kazuhiro OKI, Ashigarakami-gun (JP); Hirotoshi ANDOU, Ashigarakami-gun (JP)

(73) Assignee: FUJIFILM CORPORATION, Tokyo (JP)

(21) Appl. No.: 13/071,113

(22) Filed: Mar. 24, 2011

(30) Foreign Application Priority Data
Mar. 24, 2010 (JP) 2010-068561

(51) Int. Cl. B32B 7/00; B05D 5/12; H01L 21/20

(52) U.S. Cl. 428/336; 427/66; 438/478; 257/E21.09

(57) ABSTRACT

A novel method of forming a thin film is disclosed. The method comprises spraying a spray liquid prepared by dissolving and/or dispersing a solute in a solvent to form liquid droplets; concentrating the liquid droplets by vaporizing the solvent contained therein; and depositing the concentrated liquid droplets on a substrate or a layer formed on the substrate. In the method, liquid droplets having solid content concentration C₂ are deposited after liquid droplets having solid content concentration C₁ are deposited, provided that C₁>C₂ is satisfied.

### CROSS-REFERENCE TO RELATED APPLICATIONS

The present application claims the benefit of priority from Japanese Patent Application No. 2010-068561, filed on Mar. 24, 2010, the contents of which are herein incorporated by reference in their entirety.

### BACKGROUND OF THE INVENTION

1. Field of the Invention

The present invention relates to a method of forming a film useful for various devices such as organic electroluminescent device and solar battery, and various optical components such as reflecting plate and polarizer plate, and a film and a stacked film formed by the method.

2. Background Art

With recent expansion of network and diversification of lifestyles, electronic devices have been required to possess additional values such as mechanical flexibility and large screen size, which could not have easily been embodied by conventional silicon-base semiconductors. Organic electronics, which may be formed on film, have therefore been attracting public attention.

For various organic electronics such as organic electroluminescent device and solar battery, one important technique aimed at improving their performances may be formation of organic layers having different functions in a stacked manner. Generally known methods of forming the layer include dry process represented by vacuum evaporation, and wet process represented by spin coating.

The dry process is capable of forming homogeneous organic layers, each having a uniform thickness, in a stacked manner. The process is, however, not adoptable to thermally unstable organic materials since the materials are applied with large energy, and is adoptable only to heat-resistant substrates such as glass plate. In short, the process is limitative in terms of choice of materials to be grown and the substrate. And the vacuum process suffers also from poor productivity.

On the other hand, the wet process is capable of forming a layer readily on a flexible substrate such as a film, and is therefore far more excellent in terms of the productivity and readiness of expansion of screen size, as compared with the dry process. For example, a method of forming layer using a coating liquid prepared with organic solvent is described in “LIQUID FILM COATING”, edited by Stephan F. Kistler and Peter M. Schweizer, (published by CHAPMAN & HALL, 1997), p. 401-426, which is known as extrusion coating method. According to the wet process, it may be possible to form a stacked film by simultaneously coating. The coating method, however, needs a certain degree of viscosity of the coating liquid. Many of the materials for composing organic luminescent layers are, however, less soluble to the solvent, and may therefore be difficult to give a highly-viscous coating liquid having high concentration. It is not adequate to add any additives having thickening effects into the individual layers of organic electric devices, since addition of such thickening agents may degrade the performance. For this reason, materials for composing the organic luminescent layers often give dilute solution having only very low concentration of solid components. In order to form the organic layer having desired characteristics by using the solution of such low concentration, it is necessary to apply the solution thickly. However, it is difficult to apply the low-concentration solution thickly, and as a result, no uniform coating may be obtainable. Even if the coating method should succeed in forming a single-layered film, it may further be difficult to form the stacked film by the similar method, because the lower layer may dissolve into the solvent contained abundantly in the coated film. Use of solvent, incapable of dissolving the lower layer, may otherwise be possible, but the strategy may still suffer from a problem of limitation of solvent adoptable thereto, which means that only materials soluble to the solvent may be stacked, and that the stackable materials are therefore limited.

Also a method of forming an organic electroluminescent device based on the spray process has been proposed (see JP-A-2008-243421, for example). Even with the spray process, it is however still difficult to avoid the above-described problem of dissolution of the lower layer, in the process of forming the stacked film, due to the solvent contained in the upper layer.

Another method of forming an organic layer by depositing an aerosolized spray liquid on a substrate has been also proposed (see JP-A-2004-160388, for example). The method enables formation of film in a stacked manner without dissolving the lower layer, despite its wet nature, and may be expected to solve the problems in the dry process and wet process. From the viewpoint of avoiding dissolution of the lower layer caused by the solvent in the upper layer, smaller amount of residual solvent in the liquid droplets at the time of arriving at the substrate may be more preferable. The liquid droplets scarcely containing the solvent, however, deposit while keeping their particle geometry, so that the particle geometry will consequently be reflected to the surface morphology of the layer to be grown, and thereby the layer will finally show irregularity on the surface thereof. It is desirable for the grown layer to be smooth as possible, since the surface irregularity adversely affects the quality of contact with electrodes when the layer is finally incorporated into devices. As may be understood from the above, it has been difficult to prevent dissolution of the lower layer and to improve the smoothness of a layer at the same time. This is because, in terms of improving the smoothness, increasing the amount of solvent in the liquid droplets at the time of arriving at the substrate tends to promote dissolution of the lower layer, and, on the other hand, in terms of avoiding dissolution of the lower layer, decreasing the amount of solvent in the liquid droplets at the time of arriving at the substrate tends to degrade the surface smoothness of the grown film.

### SUMMARY OF THE INVENTION

One object of the invention is to provide a method capable of solving two problems (1) and (2) at a time: (1) dissolution of the lower layer caused by depositing the liquid droplets containing a large amount of solvent on the lower layer, and (2) degradation in smoothness of the grown layer caused by depositing the dried and aerosolized liquid droplets containing minimal amount of solvent.

More specifically, an object of the present invention is to provide a method capable of forming a film having an excellent surface smoothness by the wet process, while avoiding dissolution of the lower layer.

Under the above circumstances, the present inventors conducted various studies for solving the above-described problems, and as a result, they found that a film excellent in the surface smoothness was obtained by varying with time the solid content concentration of the liquid droplets at the time of arriving at the substrate, so as to deposit the liquid droplets having a high solid content concentration (or, having a small content of solvent) in the early stage without dissolving the lower layer, and subsequently deposit the liquid droplets having a low solid content concentration (or, having a large content of solvent)

The means for achieving the object are as follows.

[1] A method of forming a thin film comprising:

spraying a spray liquid prepared by dissolving and/or dispersing a solute in a solvent to form liquid droplets;

concentrating the liquid droplets by vaporizing the solvent contained therein; and

depositing the concentrated liquid droplets on a substrate or a layer formed on the substrate,

wherein liquid droplets having solid content concentration C₂ are deposited after liquid droplets having solid content concentration C₁ are deposited, provided that C₁>C₂ is satisfied.

[2] The method of [1], wherein the liquid droplets to be deposited contain at least one species of solvent capable of dissolving at least one material composing the substrate or the layer formed on the substrate.
[3] The method of [1] or [2], wherein the liquid droplets having solid content concentration C₁ and the liquid droplets having solid content concentration C₂ have the same solid content formulation.
[4] The method of any one of [1]-[3], wherein three or more species of liquid droplets differing in the solid content concentration from each other are deposited sequentially in the order of the solid content concentration from the higher to the lower.
[5] The method of any one of [1]-[4], wherein the liquid droplets having solid content concentration C₂ are deposited with a liquid droplet diameter D₂, after the liquid droplets having solid content concentration C₁ are deposited with a liquid droplet diameter D₁, provided that C₁>C₂ and D₁<D₂ are satisfied.
[6] The method of any one of [1]-[5], wherein, after the liquid droplets having solid content concentration C₁ are deposited, the solid content concentration of the liquid droplets to be disposed is varied from C₁ to C₂ by adjusting concentration of the spray liquid pumped to a nozzle.
[7] The method of [6], wherein two or more nozzles are used, and the solid content concentration of the liquid droplets to be disposed is varied from C₁ to C₂ by spraying two or more spray liquids, differing in solid content concentration from each other, from the two or more nozzles respectively according to time control.
[8] The method of any one of [1]-[5], wherein the solid content concentration of the liquid droplets to be disposed is varied from C₁ to C₂ by adjusting concentrating conditions of the liquid droplets.
[9] The method of [8], wherein the solid content concentration of the liquid droplets to be disposed is varied from C₁ to C₂ by adjusting a temperature of an atmosphere, through which the liquid droplets pass from spraying to depositing on the substrate or the layer formed on the substrate, according to the time.
[10] The method of any one of [1]-[5], wherein the solid content concentration of the liquid droplets to be disposed is varied from C₁ to C₂ by adjusting a liquid droplet diameter at the time of spraying.
[11] The method of any one of [1]-[10], wherein the spray liquid contains at least one species selected from organic semiconductor, organic luminescent material, organic electron transfer material, and organic hole transfer material.
[12] The method of any one of [1]-[11], to be used for forming any one of organic semiconductor layer, luminescent layer, electron transporting layer, electron injection layer, hole transporting layer, and hole injection layer.
[13] A method of forming a stacked film comprising at least:

forming a lower single-layered film having a homogenous solid content formulation, according to a method of any one of [1]-[12]; and

forming, on the lower single-layered film, an upper single-layered film having a solid content formulation partially or wholly different from that of the lower single-layered film, according to a method of any one of [1]-[12].

[14] A stacked film formed according to a method described in any one of [1]-[12] or [13], having a zone where the lower layer and the upper layer mix with each other, the thickness of the zone being equal to or less than 10 nm.

### BRIEF DESCRIPTION OF THE DRAWINGS

FIG. 1 is a schematic drawing of an exemplary spray-type film forming apparatus capable of carrying out the method of the present invention.

Reference numerals used in the drawing are as follow:
10 spray-type film forming apparatus
12 dual fluid nozzle
14 chamber
16 syringe pump
18 regulator
20 gas bomb
22 substrate
24 substrate holder

### DETAILED DESCRIPTION OF THE INVENTION

The present invention will be detailed below.

The present invention relates to a method of forming a thin film comprising:

spraying a spray liquid prepared by dissolving and/or dispersing a solute in a solvent to form liquid droplets;

concentrating the liquid droplets by vaporizing the solvent contained therein; and

depositing the concentrated liquid droplets on a substrate or a layer formed on the substrate,

wherein liquid droplets having solid content concentration C₂ are deposited after liquid droplets having solid content concentration C₁ are deposited, provided that C₁>C₂ is satisfied.

One feature of the method of the present invention resides in that the solid content concentration of the liquid droplets at the time of arriving at the surface of substrate is varied with time. More specifically, in the present invention, the liquid droplets having a high solid content concentration (or, having a small content of solvent) are deposited in the early stage, so as to enable film formation based on deposition of the liquid droplets, without dissolving the lower layer (the lower layer may be a substrate or may be a thin layer such as organic film). The liquid droplets having a low solid content concentration (or having a large content of solvent) are then deposited, and the liquid droplets may spread over the deposited surface, which enables formation of film having an excellent surface smoothness by the surface-leveling property.

The individual steps of the method according to the present invention will be described in detail below.

### (1) Step of Forming Liquid Droplets

First, a spray liquid (source liquid) prepared by dissolving and/or dispersing an organic material in a solvent is sprayed, to thereby form liquid droplets. The material and solvent used for preparing the spray liquid are not specifically limited, and may be selected form a variety of materials suitable for forming an organic thin film having desired physical characteristics. In the method of present invention, the materials are not limited in terms of heat resistance, because the materials are not exposed to extremely high temperature. The materials may be selected from high-molecular-weight materials, low-molecular-weight materials, and even from metal complexes. The solvent may be selected from those appropriate in terms of affinity to the materials. Of course, water may be adoptable as the solvent, and the same may apply also to mixed solvent of water and organic solvent. Solvents suitable for spraying include tetrahydrofuran, methyl ethyl ketone, toluene, methanol, ethanol, hexane, benzene, acetone, diethyl ether, cyclohexanone, chlorobenzene, and chloroform.

At least one species of the solvent used for preparing the spray liquid may also be a solvent which possibly dissolves any material(s) for composing the substrate or a layer formed on the substrate, on which the liquid droplets are deposited. This is because the liquid droplets which arrive at the substrate or the layer in the early stage of deposition has a high concentration of solid component, or has a small content of solvent, so that the substrate or the like may dissolve into the solvent in the liquid droplets only to a slight degree. In addition, the dissolution of the substrate into such slight amount of solvent may promote bonding between the deposited film to be grown and the underlying substrate, so that the adhesiveness may desirably be improved. In particular in organic electronic devices, the performance may be improved since influence of interface, which possibly serves as a barrier against migration of electrons and holes, may be moderated. On the other hand, by depositing the liquid droplets having a larger content of solvent, the liquid droplets may spread at the time of arriving at the surface, and dissolve a minimal part of the surface of the film already formed in the early stage, which may cause the leveling property and improve the smoothness of the film.

In the step of forming the liquid droplets, the spray liquid is sprayed to form the liquid droplets. Various methods of forming the liquid droplets may be adoptable without special limitation. For example, by mixing the spray liquid with a carrier gas supplied at a predetermined pressure and flow rate, the spray liquid may become the liquid droplets floated in the carrier gas. The carrier gas is not specifically limited, to which also air may be adoptable. In view of avoiding denaturation of the source materials, the carrier gas is preferably an inert gas exemplified by nitrogen, argon, helium and so forth. The pressure and flow rate of carrier gas may be controlled using a regulator. The liquid droplets may be formed also by making use of ultrasonic vibration.

While the diameter of the liquid droplets is not specifically limited, it preferably falls in the range from 0.1 to 100 μm or around in general, and more preferably in the range from 1 to 10 μm or around. While narrower distribution of the diameter of the liquid droplets to be produced is more preferable, a certain range of distribution is inevitable. In general, the liquid droplets shows a distribution of diameter of 1 to 100 μm.

While also the concentration of the spray liquid to be sprayed is not specifically limited, it preferably falls in the range from 0.00001 to 1% by mass in general, and more preferably in the range from 0.0001 to 0.01% by mass, since many of organic materials used for the organic electronic devices are less soluble.

Materials adoptable to a solute of the spray liquid to be sprayed may be selected typically from organic materials used for fabricating the individual organic films composing organic electronic devices such as organic EL. One example may be an organic material used for a luminescent layer of organic EL, and may be an organic compound used as luminescence material and host material. Various compounds for composing the individual organic thin films of the organic EL device, and adoptable to the solute of the spray liquid in the method of producing according to the present invention, will be detailed later.

### (2) Step of Concentrating

Next, the liquid droplets formed in the above-described step are concentrated. The liquid droplets are preferably produced in a partitioned space such as a chamber, and are jetted from an opening of the chamber having a predetermined geometry towards the substrate. Before being jetted from the opening of the chamber towards the substrate, the liquid droplets are preferably heated. By the heating, the solvent contained in the liquid droplets are removed, and thereby the liquid droplets are converted into a mist having a high concentration of solid component and small diameter. The temperature of heating may preferably be adjusted not so as to exceed the boiling point of the solvent used for preparing the spray liquid.

### (3) Step of Depositing

Next, the liquid droplets are deposited onto the substrate, thereby forming a thin film. In the present invention, the solid content concentration of the liquid droplets at the time of arriving at the surface of substrate is varied with time. More specifically, after the liquid droplets having solid content concentration C₁ are deposited, the liquid droplets having solid content concentration C₂, where C₁>C₂ is satisfied, are deposited. The ratio of C₁ and C₂ may be determined depending on species of the solute to be selected, degree of surface smoothness of the film to be formed, the thickness of film and so forth. Any embodiments wherein a ratio of C₁ to C₂, C₁/C₂, is equal to or larger than 2 may successfully exhibit the effects of the present invention. In the method for forming a thin-film employing the spray method, the upper limit of C₁/C₂ is approximately 1000. Note that the “solid content concentration” of the liquid droplets herein means the concentration of the solute which remains after removing the solvent from the liquid droplets.

In general, when the liquid droplets having the same solid content concentration are concentrated, the liquid droplets having a larger solid content concentration may have a smaller diameter. Accordingly, in one embodiment of the present invention, the liquid droplets having solid content concentration C₁ and diameter D₁ are deposited, and then the liquid droplets having solid content concentration C₂ and diameter D₂, which satisfy C₁>C₂ and D₁<D₂, are deposited. The present invention is, however, not limited to this embodiment, since the relation between the solid content concentration and the diameter of the liquid droplets is not always given as described in the above, as a result of adjustment of conditions of spraying and so forth.

In one embodiment of the present invention, the liquid droplets having solid content concentration C₁ and the liquid droplets having solid content concentration C₂ have the same solid content formulation. In other words, a single-layered film having a homogenous composition is formed in this embodiment. Note that “the same solid content formulation” herein means that the material composing the film is the same, and even the compositional ratios thereof are same for the case where a plurality of materials are used. In this embodiment, the liquid droplets having solid content concentration C₁ and solid content concentration C₂ have the same solid content formulation, and thereby gives a single-layered film upon removal of the solvent after the deposition.

The solid content concentration of the liquid droplets at the time of arriving at the surface of the substrate on which the film is grown may be varied from C₁ to C₂ by adjusting at least one of:

conditions of condensation of the liquid droplets in the condensation step;

the solid content concentration of the spray liquid to be sprayed in the step of forming liquid droplets; and

the liquid droplets diameter at the time of spraying in the step of forming liquid droplets;

according to the time. The variation may be carried out continuously or discontinuously. According to one embodiment of the former, the liquid droplets having solid content concentration C₁ are deposited, and then the solid content concentration of the liquid droplets to be deposited may be varied up to C₂, typically by adjusting concentration of the spray liquid.

According to one example, the solid content concentration of the liquid droplets at the time of arriving at the substrate or the like is varied in the condensation step. More specifically, the temperature of an atmosphere, through which the sprayed liquid droplets travel towards the substrate, is adjusted. A higher temperature of the atmosphere may result in a higher solid content concentration of the liquid droplets, at the time of arriving at the substrate after traveling through the atmosphere. For this reason, the temperature of the atmosphere through which the liquid droplets travel is set higher in the early stage of deposition. Thereafter, by lowering the temperature of the atmosphere through which the liquid droplets travel, the liquid droplets having a low solid content concentration, or containing a larger amount of solvent, may be deposited on the particle-deposited film preliminarily formed in the early stage. The liquid droplets having a low solid content concentration and a larger amount of solvent readily spreads over the particle-deposited film, and forms a highly smooth film by virtue of their leveling effect.

In this example, the liquid droplets preferably travel through the inner space of a chamber which is controllable with respect to the internal temperature thereof, and reach the surface of substrate or the like. For example, it may be preferable to dispose a heating unit, such as heater, or flow path for hot water/hot air, around the chamber, so as to control the inner space of the chamber. For example, the internal temperature of the chamber may be kept at T₁° C. over a predetermined duration from the start of spraying of the liquid droplets, and after the elapse of the predetermined duration, the temperature may be lowered to T₂° C. (T₁>T₂), so as to allow the liquid droplets having solid content concentration C₁ to deposit over the duration in which the internal temperature of the chamber is kept at T₁° C., and so as to allow the liquid droplets having solid content concentration C₂ to deposit over the duration in which the internal temperature of the chamber is kept at T₂° C. The solid content concentration C₁ of the liquid droplets to be deposited may continuously vary up to C₂, if the spraying is continued over the duration in which the internal temperature of the chamber is lowered from T₁° C. to T₂° C., whereas the solid content concentration C₁ of the liquid droplets to be deposited may discontinuously vary up to C₂, if the spraying is interrupted over the duration in which the internal temperature of the chamber is lowered from T₁° C. to T₂° C., and re-started at T₂° C.

The conditions of condensation in the condensation process include distance of travel of the sprayed liquid droplets up to the substrate. A longer distance, or a longer time for the liquid droplets to travel through the heated atmosphere, will result in a higher solid content concentration of the liquid droplets at the time of arriving at the substrate, whereas a shorter distance, or a shorter time for the liquid droplets to travel through the heated atmosphere, will result in a lower solid content concentration of the liquid droplets at the time of arriving at the substrate. Accordingly, typically by altering position of a nozzle through which the liquid droplets are jetted, and/or by altering position of the surface of the substrate which allows deposition to proceed thereon, the solid content concentration of the liquid droplets at the time of arriving at the substrate or the like may be adjusted.

In this example, a movable supporting member is preferably used as a support for the substrate and/or nozzle.

Also time control of internal pressure of the chamber may exhibit similar effects, since pressure of the atmosphere through which the liquid droplets travel may affect the degree of condensation of the liquid droplets.

Another example capable of adjusting the solid content concentration of the liquid droplets at the time of arriving at the substrate or the like relates to a method of adjusting the solid content concentration of the spray liquid used for the step of forming the liquid droplets. More specifically, two o more spray liquids having a solid content concentration different from each other are prepared, and the spray liquid having the highest solid content concentration may be sprayed in the early stage so as to produce the liquid droplets having a high solid content concentration, and to allow them to deposit on the surface of the substrate or the like to thereby form a particle-deposited film, and then the spray liquid having the lower solid content concentration may be sprayed so as to produce the liquid droplets having a low solid content concentration, and to allow them to deposit on the particle-deposited film preliminarily formed in the early stage. The liquid droplets, which have a low solid content concentration and contain a large amount of solvent, may readily spread over the particle-deposited film, and may form a highly smooth film by virtue of their leveling effect.

Since two or more spray liquids having a solid content concentration different from each other are used in this example, two or more nozzles through which the liquid droplets are jetted may be used. By using two or more nozzles, the solid content concentration of the liquid droplets may be varied with time, by controlling ON/OFF operation of spraying through the individual nozzles according to the time. Of course, the spray liquids having a concentration different from each other may be sprayed to produce the liquid droplets out through a single nozzle. In this example, a single nozzle may be supplied with the spray liquids having a concentration different from each other from two or more supply ports. By controlling ON/OFF operation of supply of the spray liquids from the individual supply ports according to the time, two or more spray liquids having a concentration different from each other may be sprayed from a single nozzle to produce the liquid droplets.

In this example, two or more spray liquids having a solid content concentration different from each other are prepared. Ratio of concentrations of the individual spray liquids may be determined depending on species of solutes, required level of surface smoothness of the film to be formed, thickness of the film and so forth. In one exemplary case, a spray liquid having a concentration of 0.0001 to 1% by mass is sprayed to produce the liquid droplets in the early stage, and then a spray liquid having a concentration of 0.00001 to 0.1% by mass is sprayed to produce the liquid droplets.

Another example of adjustment of the solid content concentration of the liquid droplets relates to a method of adjusting conditions of spraying in the step of forming the liquid droplets. In general, the spray liquid may be sprayed to produce the liquid droplets after being mixed with a pressurized gas, wherein the diameter of liquid droplets may be varied with time, typically by controlling flow rate of the spray liquid per unit time, and/or flow rate of the gas per unit time, according to the time. Since a smaller diameter of the liquid droplets consequently means a small amount of solvent and a high solid content concentration, so that the conditions of spraying may be controlled so that the liquid droplets having a smaller diameter may be sprayed in the early stage, and so that the liquid droplets having a larger diameter may be sprayed after the elapse of a predetermined duration. According to this example, an effect similar to that obtained by the method of using two or more spray liquids having a solid content concentration different from each other, may be obtained by using one spray liquid having a solid content concentration.

In the method of the present invention, three or more liquid droplets having a solid content concentration different from each other may sequentially be deposited in decreasing order of the solid content concentration. More specifically, after the liquid droplets having solid content concentration C₂ are deposited, the liquid droplets having solid content concentration C₃, where C₂>C₃ is satisfied, may be deposited. Furthermore, liquid droplets having a solid content concentration smaller than C₃ may be deposited once or more after the deposition of the liquid droplets having solid content concentration C₃.

### (4) Step of Stacking

The present invention is also effective as a method of preparing a stacked film. By repeating the above-described steps (1) to (3) n times (where, n is an integer of 2 or larger), n-layered stacked film may be prepared. More specifically, after a single-layered film (lower film) having a high surface smoothness and a single solid content formulation is formed by the above-described steps (1) to (3), such steps (1) to (3) may be repeated on the thus-formed lower film using the spray liquids having a different solid content formulation so as to form an upper film, to thereby prepare the stacked film. Since also the upper film is formed by the steps (1) to (3), the dissolution of the lower film due to the solvent contained in the liquid droplets for forming the upper film may be avoidable, and thereby the stacked film having an excellent surface smoothness may be prepared. The spray liquid to be used for forming the upper film and the spray liquid to be used for forming the lower film are different from each other at least in the solid content formulation. For example, they may be different in one or more species of the constituents, and/or in the ratio of constituents.

In an exemplary process of forming a single-layered film (lower film) composed of material “A” by the steps (1) to (3), and then forming thereon a single-layered film (upper film) composed of material “B” by repeating such steps (1) to (3), a trace amount of solvent, intentionally allowed to remain in the early stage, allows growth of the upper film to proceed while slightly dissolving the surficial portion of the lower film. In this way, not only adhesiveness between the lower film and the upper film may be improved, but also the boundary between the upper film and lower film may become obscure, so as to give a thickness-wise concentration gradient of the materials A/B. Such configuration may typically moderate obstacles against mobility of electrons/holes, and may consequently improve performance of devices. According to the present invention, thickness of a zone where the lower film and the upper film mix with each other may be adjusted to not larger than 10 nm. In other words, the thickness of the zone where the lower film and the upper film mix with each other may be adjusted to several nanometers or around.

While the thickness of the film formed by the method of the present invention is not specifically limited, the present invention is particularly advantageous for formation of films, particularly those having a thickness of 0.01 to 10 μm or around. The thickness of the film is more preferably 0.01 to 1 μm, and still more preferably 0.01 to 0.1 μm.

It is preferable to allow the liquid droplets having solid content concentration C₁ to deposit to as thick as 1 to 50 nm or around in the early stage of deposition, and then to allow the liquid droplets having solid content concentration C₂, which is lower than C₁, to deposit up to a desired thickness depending on needs.

In the present invention, a gas may be allowed to flow in the direction same as the direction of generation of mist, or the direction towards the substrate. The gas is preferably an inert gas, to which nitrogen, argon, helium or the like may preferably be adoptable. Rate of formation of the film may be improved by supplying the gas.

In the present invention, the surface of the substrate or the like, on which the deposition proceeds, may partially or totally be given with a certain potential. By placing the substrate at a certain potential so as to ensure a potential difference with respect to the liquid droplets, the substrate will have an increased force of attracting the liquid droplets, and thereby tendency of adhesion of the liquid droplets to other sites may be reduced, and the rate of formation of the film may be improved. Provision of a certain potential to the substrate also enables adjustment of density of the organic film. In an embodiment where the liquid droplets are electrically charged, the substrate may preferably be given a reversal potential with respect to the liquid droplets. More specifically, the substrate is preferably given an electric charge opposite to the electric charge owned by the liquid droplets, so as to ensure a certain potential difference therebetween.

As described in the above, the surface of the substrate or the like, on which the deposition proceeds, may partially be given a certain potential, so as to form the organic film into a desired pattern or geometry.

If necessary, the thus-formed film may further be dried. The drying may be carried out by supplying heat to the substrate typically through supporting members of the substrate, so as to preheat the surface of the substrate up to high temperatures. The drying may alternatively be accomplished by blowing hot air. The drying is preferable since the solvent remaining in the thus-formed film may be removed.

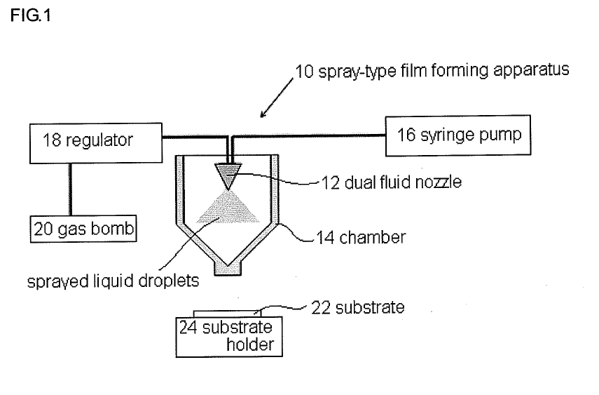

FIG. 1 is a schematic drawing illustrating an exemplary configuration of a spray-type film forming apparatus with which the inventive method of forming a film may be embodied.

A spray-type film forming apparatus 10 illustrated in FIG. 1 is configured so that spray liquid supplied from a syringe pump 16 is mixed with a gas (N₂ gas, for example), which is supplied from a gas bomb 20 at a flow rate regulated by a regulator 18, in a dual fluid nozzle 12, and sprayed into a chamber 14 so as to produce the liquid droplets. Temperature of the inner space of the chamber 14 is controllable typically by a heater provided to the outer circumference thereof, or by hot water/hot air allowed to flow through a flow path provided to the outer circumference thereof. The liquid droplets jetted out from the nozzle 12 are concentrated in the chamber 14, and the concentrated liquid droplets deposit on the surface of a substrate 22 supported by a substrate holder 24, to thereby form a film.

In one embodiment of the method of the present invention, a heating means such as the heater for heating the inner space of the chamber 14 is controlled on the time basis, wherein the heating is controlled at high temperatures in the early stage of deposition, and then controlled to lower the temperature of the inner space of the chamber 14 after the elapse of a predetermined duration.

In another embodiment, the substrate holder 24 is configured to be movable up and down, position of which is controlled on the time basis, wherein the control is effected so as to set, in the early stage of deposition, a long distance between the dual fluid nozzle 12 and the surface of the substrate on which the deposition proceeds, and so as to shorten the distance between the dual fluid nozzle 12 and the surface of the substrate on which the deposition proceeds, after the elapse of a predetermined duration.

In still another embodiment, the syringe pump 16 is configured to supply a plurality of spray liquids having different levels of solid content concentration to a fluid nozzle, and to control ON/OFF operation of supply of the spray liquids from the individual supply ports, wherein the control is effected so as to supply, in the early stage of deposition, a spray liquid having a high solid content concentration, and so as to change the spray liquid into the one having a low solid content concentration, after the elapse of a predetermined duration.

In still another embodiment, the substrate holder 24 is configured to be movable in the horizontal direction, such as moving through a flow path having a plurality of spray-type film forming units illustrated in FIG. 1 disposed therealong, while holding thereon the substrate 22. In the early stage of deposition, the liquid droplets having a high solid content concentration are deposited on the surface of the substrate 22 to thereby form a particle-deposited film, in a first spray-type film forming unit in which temperature of the inner space of the chamber 14 is set to high temperatures, and/or the liquid droplets of the spray liquid having a high solid content concentration are sprayed. After the elapse of a predetermined duration, the substrate holder 24 horizontally moves to a second spray-type film forming unit in which temperature of the inner space of the chamber 14 is set lower than in the first unit, and/or the liquid droplets of the spray liquid having a solid content concentration lower than in the first unit are sprayed, and thereby the liquid droplets having a low solid content concentration, or having a large content of solvent, are deposited on the particle-deposited film formed in the first unit. Thereby, a film having an excellent surface smoothness is formed.

Note that three or more spray-type film forming units may be disposed.

In still another embodiment, the syringe pump 16 may be controlled so as to vary the flow rate per unit time of the spray liquid to be pumped to the nozzle 12 in a time-series manner, and/or the regulator 18 may be controlled so as to vary the flow rate per unit time of the pressurized gas to be pumped to the nozzle 12 in a time-series manner, to thereby make the nozzle 12 spray the liquid droplets having a small diameter, of having a high solid content concentration, in the early stage of deposition, and after the elapse of a predetermined duration, to thereby make the nozzle 12 spray the liquid droplets having a large diameter, or having a low solid content concentration.

Note that the spray-type film forming apparatus illustrated in FIG. 1 is merely an exemplary one, and is therefore not limited by the configuration shown herein. The spray-type film forming apparatus illustrated in FIG. 1 may further have a voltage application unit for giving a certain potential to the substrate, a blower unit for blowing inert gas or the like in the direction of spraying in the chamber, and an exhaust port for discharging the gas in the chamber.

In the present invention, there is no special limitation on materials for composing the substrate on which the liquid droplets are deposited. For example, the substrate may be composed of inorganic materials such as metal, metal oxides, glass, silicon and so forth; or may be composed of organic materials such as polymer materials. Both substrates may have a layer which contains an inorganic material and/or organic material, so that the organic film may be formed by depositing the liquid droplets on such layer. For example, the liquid droplets may be deposited over an inorganic film such as ITO film, or over an organic film typically composed of PTPDES-2, PEDOT-PSS, TPD, NPD or the like.

The method of the present invention is useful for forming thin films composed of organic materials (complexes having organic molecules as the ligands also included) which are not suitable for dry process such as vacuum evaporation. In particular, since most of materials used for organic electronic devices, such as organic semiconductor, organic light-emitting material, organic electron transfer material, and organic hole transfer material, are scarcely soluble, so that the present invention is useful for forming films composed of such materials. The method of the present invention is especially useful for formation of organic semiconductor layer, luminescent layer, electron transporting layer, electron injection layer, hole transporting layer, and hole injection layer of organic electronic devices, for which excellent surface smoothness is required.

In the embodiments for forming an organic EL layer according to the method of the invention, examples of the solute in the spray liquid include organic compound to be used as an emitting or host material. Examples of the material for emission layers which can be used in the invention as a solute in the spray liquid include, but are not limited to, those shown below.

### (i) Emitting Material

Examples of the emitting material for organic EL layers include fluorescent and phosphorescent materials. According to the invention, the solute in the spray liquid may be any of them.

### (a) Phosphorescent Material

Examples of the phosphorescent material generally include metal complexes containing a transition metal or lanthanoid atom. Examples of the transition metal atom include ruthenium, rhodium, palladium, tungsten, rhenium, osmium, iridium and platinum; and preferable examples of the transition metal atom include rhenium, iridium and platinum.

Examples of the lanthanoid atom include lanthanum, cerium, praseodymium, neodymium, samarium, europium, gadolinium, terbium, dysprosium, holmium, erbium, thulium, ytterbium and lutetium; preferable examples of the lanthanoid atom include neodymium, europium and gadolinium.

Examples of the ligand of the complex include those described in “Comprehensive Coordination Chemistry” written by G. Wilkinson, published by Pergamon Press in 1987; those described in “Photochemistry and Photophysics of Coordination Compounds” written by H. Yersin, published by Springer-Verlag in 1987; and those described in “Organic Metal Chemistry-Foundation and Application” written by Akio Yamamoto, published by SHOKABO PUBLISHING Co., Ltd. in 1982.

Specific examples of the ligand include halogen ligands (preferably chlorine ligand), aryl carbocyclic ring ligands (for example, cyclopentadienyl anion, benzene anion or naphthyl anion), nitrogen-containing heterocyclic ligands (for example, phenyl pyridine, benzoquinoline, quinolinol, bipyridyl, or phenanthroline), diketone ligands (for example, acetyl acetone), carboxylic acid ligands (for example, acetic acid ligand), alcoholate ligands (for example phenolate ligand), carbon monoxide ligand, isonitrile ligand, and cyano ligand; nitrogen-containing heterocyclic ligands are preferable.

The metal complex may have one transition metal atom, may be dinuclear complexes having two or more transition metal atoms or may have heterogeneous metal atoms.

Examples of the emitting material include also phosphorescent materials described in U.S. Pat. No. 6,303,238B1, U.S. Pat. No. 6,097,147, WO00/57676, WO00/70655, WO01/08230, WO01/39234A2, WO01/41512A1, WO02/02714A2, WO02/15645A1, WO02/44189A1, JP-A-2001-247859, JP-A-2002-302671, JP-A-2002-117978, JP-A-2002-225352, JP-A-2002-235076, JP-A-2003-123982, JP-A-2002-170684, EP 1211257, JP-A-2002-226495, JP-A-2002-234894, JP-A-2001-247859, JP-A-2001-298470, JP-A-2002-173674, JP-A-2002-203678, JP-A-2002-203679, JP-A-2004-357791, and JP-A-2006-256999.

### (b) Fluorescent Material

Examples of the fluorescent dopant generally include benzoxazole, benzimidazole, benzothiazole, styrylbenzene, polyphenyl, diphenyl butadiene, tetraphenyl butadiene, naphthalimide, coumalin, pyran, perinone, oxadiazole, aldazine, piralidine, cyclopentadiene, distyrylanthracene, quinacridone, pyrrolopridine, thiadiazolopyridine, styrylamine, aromatic dimethylidyne compounds, condensation polycyclic aromatic compounds (for example, anthracene, phenanthroline, pyrene, perylene, rubrene or pentacene), metal complexes of 8-quinolinol, metal complexes such as pyrromethen complexes and rare-earth complexes, polymers such as polythiophene, polyphenylene and polyphenylene vinylene, and organic silane compounds and derivatives thereof.

### (ii) Host Material

As the host materials of organic EL layers, hole transporting materials and electron transporting materials are known. According to the invention, the solute may be any of them.

### (a) Electron Transporting Material

In terms of high-durability or low-driving voltage, the electron transporting materials, having the electron affinity Ea of from 2.5 eV to 3.5 eV, more preferably even more preferably from 2.6 eV to 3.4 eV, or from 2.8 eV to 3.3 eV, are preferable.

Examples of such an electron transporting material include pyridine, pyrimidine, triazine, imidazole, pyrazole, triazole, oxazole, oxadiazole, fluorene, anthraquinone dimethane, anthrone, diphenyl quinine, thiopyran dioxide, carbodiimide, luorenylidenemethane, distyrylpyrazine, fluorinated aromatic compounds, tetracarboxylic anhydride of aromatic ring such as naphthalene and perylene, phthalocyanine and derivatives thereof (may be condensed with other ring(s)), and metal complexes such as metal complexes of 8-quinolinol, metal phthalocyanine and metal complexes having benzoxazole or benzothiazole ligand.

As the electron transporting material, metal complexes, azole derivatives (including benzimidazole derivatives, imidazopyridine derivatives), azine derivatives (including pyridine derivatives, pyrimidine derivatives and triazine derivatives) are preferable; and metal complexes are more preferable, in terms of high durability.

The metal complexes having ligand(s) including at least one nitrogen, oxygen or sulfur atom coordinate-bonding to the metal atom are preferable.

The metal ion of the metal complex is not limited. Beryllium ion, magnesium ion, aluminum ion, gallium ion, zinc ion, indium ion, tin ion, platinum ion, and palladium ion are preferable; beryllium ion, aluminum ion, gallium ion, zinc ion, platinum ion, and palladium ion are more preferable; and aluminum ion, zinc ion, platinum ion, and palladium ion are even more preferable.

Examples of the ligand in the metal complex include various known ligands such as those described in “Photochemistry and Photophysics of Coordination Compounds” written by H. Yersin, published by Springer-Verlag in 1987; and those described in “Organic Metal Chemistry-Foundation and Application” written by Akio Yamamoto, published by SHOKABO PUBLISHING Co., Ltd. in 1982. As the ligands, preferred are nitrogen-containing heterocyclic ligands (preferably having 1 to 30 carbon atoms, more preferably having 2 to 20 carbon atoms, particularly preferably having 3 to 15 carbon atoms). The ligands may be monodentate ligands or bidentate or higher ligands, but are preferably from bidentate ligands to hexadentate ligands, and mixed ligands of a monodentate ligand with a bidentate to hexadentate ligand are also preferable.

Specific examples of the ligands include azine ligands (e.g. pyridine ligands, bipyridyl ligands, terpyridine ligands, etc.); hydroxyphenylazole ligands (e.g. hydroxyphenyzenzimidazole ligands, hydroxyphenylbenzoxazole ligands, hydroxyphenylimidazole ligands, hydroxyphenylimidazopyridine ligands, etc.); alkoxy ligands (e.g. methoxy, ethoxy, butoxy and 2-ethylhexyloxy ligands, and these ligands preferably have 1 to 30 carbon atoms, more preferably have 1 to 20 carbon atoms, particularly preferably have 1 to 10 carbon atoms); aryloxy ligands (e.g. phenyloxy, 1-naphthyloxy, 2-naphthyloxy, 2,4,6-trimethylphenyloxy, and 4-biphenyloxy ligands, and these ligands preferably have 6 to 30 carbon atoms, more preferably have 6 to 20 carbon atoms, particularly preferably have 6 to 12).

In addition to the above, specific examples thereof include heteroaryloxy ligands (e.g. pyridyloxy, pyrazyloxy, pyrimidyloxy, quinolyloxy ligands and the like, and those having preferably 1 to 30 carbon atoms, more preferably 1 to 20 carbon atoms, and particularly preferably 1 to 12 carbon atoms); alkylthio ligands (e.g. methylthio, ethylthio ligands and the like, and those having preferably 1 to 30 carbon atoms, more preferably 1 to 20 carbon atoms, and particularly preferably 1 to 12 carbon atoms); arylthio ligands (e.g. phenylthio ligands and the like, and those having preferably 6 to 30 carbon atoms, more preferably 6 to 20 carbon atoms, and particularly preferably 6 to 12 carbon atoms); heteroarylthio ligands (e.g. pyridylthio, 2-benzimidazolylthio, 2-benzoxazolylthio, 2-benzothiazolylthio ligands and the like, and those having preferably 1 to 30 carbon atoms, more preferably 1 to 20 carbon atoms, and particularly preferably 1 to 12 carbon atoms); siloxy ligands (e.g. a triphenylsiloxy group, a triethoxysiloxy group, a triisopropylsiloxy group and the like, and those having preferably 1 to 30 carbon atoms, more preferably 3 to 25 carbon atoms, and particularly preferably 6 to 20 carbon atoms); aromatic hydrocarbon anion ligands (e.g. a phenyl anion, a naphthyl anion, an anthranyl anion and the like, and those having preferably 6 to 30 carbon atoms, more preferably 6 to 25 carbon atoms, and particularly preferably 6 to 20 carbon atoms); aromatic heterocyclic anion ligands (e.g. a pyrrole anion, a pyrazole anion, a triazole anion, an oxazole anion, a benzoxazole anion, a thiazole anion, a benzothiazole anion, a thiophene anion, a benzothiophene anion and the like, and those having preferably 1 to 30 carbon atoms, more preferably 2 to 25 carbon atoms, and particularly preferably 2 to 20 carbon atoms); and indolenine anion ligands. Among these, nitrogen-containing heterocyclic ligands, aryloxy ligands, heteroaryloxy groups, siloxy ligands are preferable. Nitrogen-containing aromatic heterocyclic ligands, aryloxy ligands, siloxy ligands, aromatic hydrocarbon anion ligands, and aromatic heterocyclic anion ligands are more preferable.

Examples of the metal complex electron transporting hosts include compounds described, for example, in JP-A-2002-235076, JP-A-2004-214179, JP-A-2004-221062, JP-A-2004-221065, JP-A-2004-221068 and JP-A-2004-327313.

Examples of the electron transporting material include, but are not limited to, those shown below.

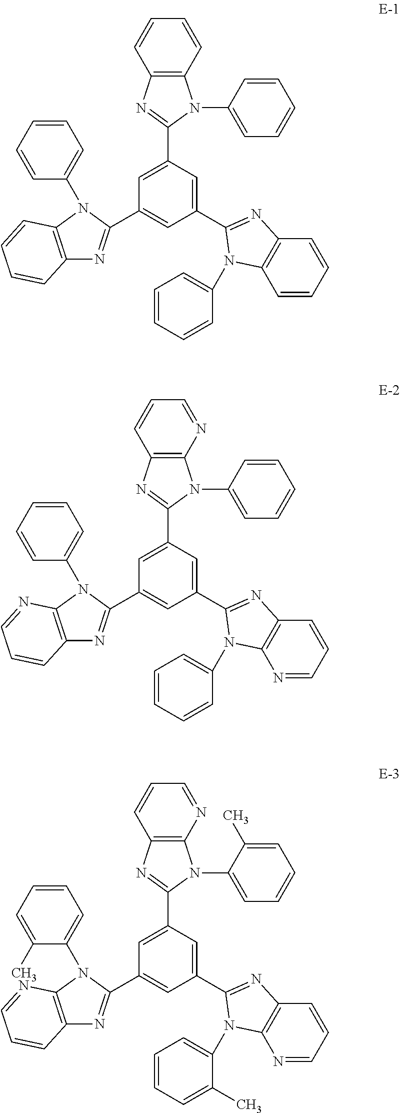

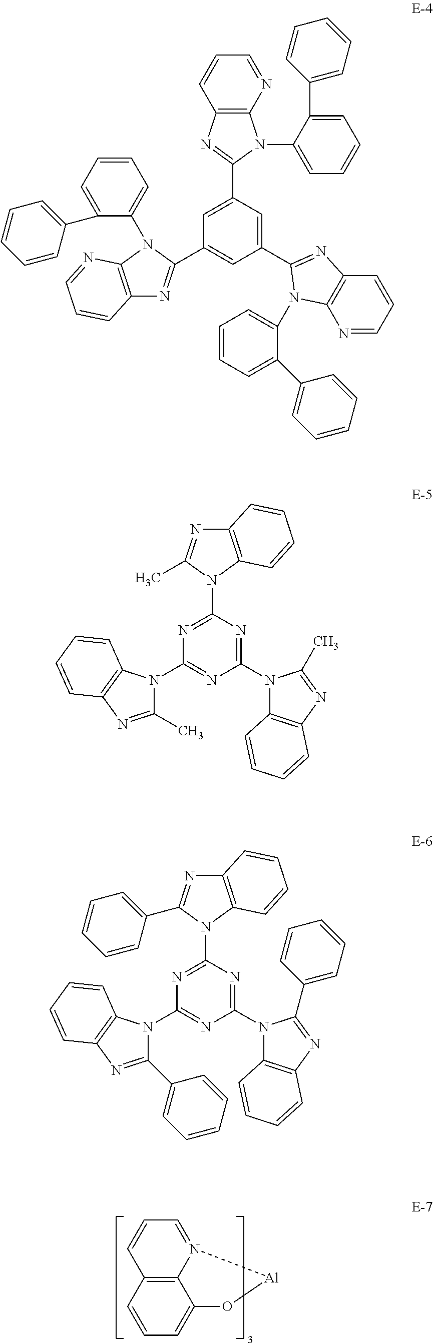

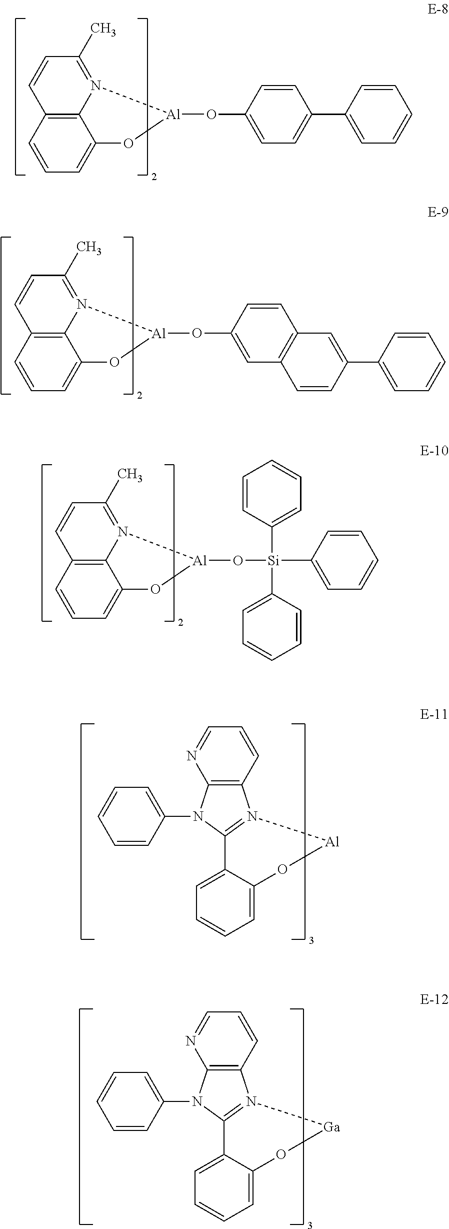

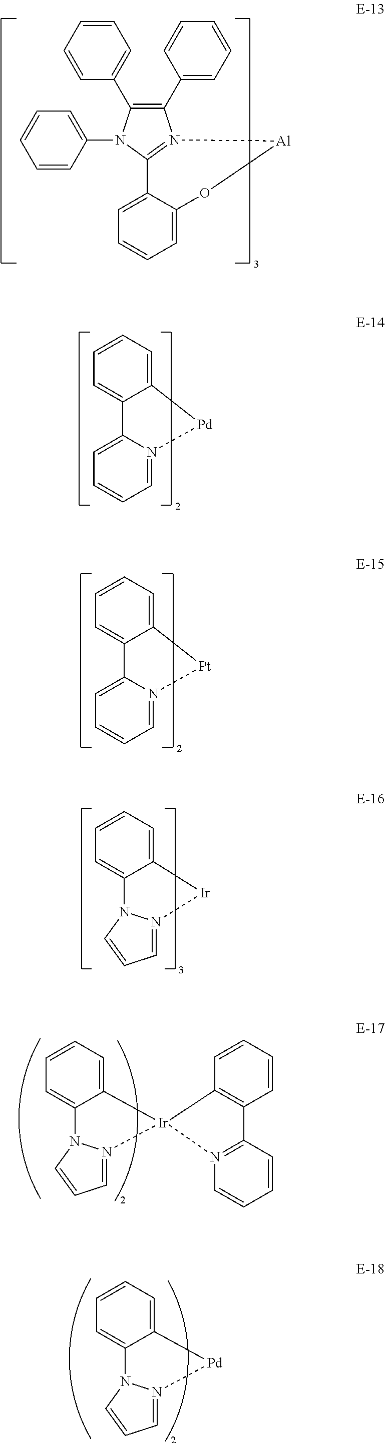

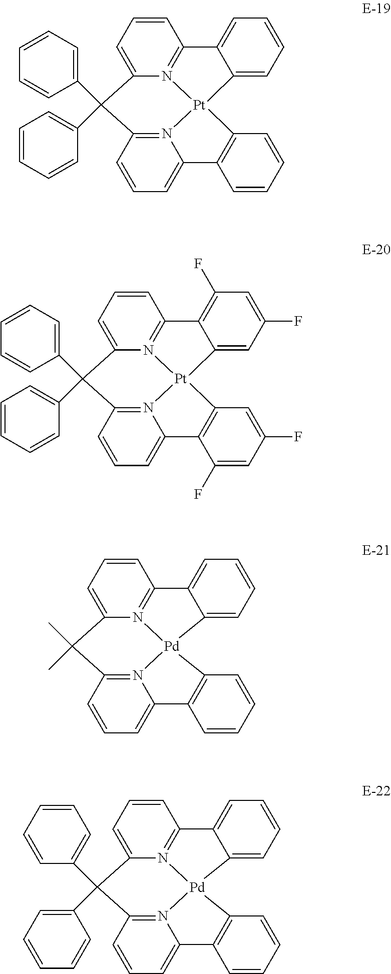

As the electron transporting host, E-1 to E-6, E-8, E-9, E-10, E-21, or E-22 is preferred, E-3, E-4, E-6, E-8, E-9, E-10, E-21, or E-22 is more preferred, and E-3, E-4, E-21, or E-22 is even more preferred.

### (b) Hole Transporting Host Material

The hole transporting host material used in the light-emitting layer of the present invention preferably has an ionization potential Ip of from 5.1 eV to 6.4 eV, more preferably from 5.4 eV to 6.2 eV, and even more preferably from 5.6 eV to 6.0 eV in terms of improvement in durability and decrease in driving voltage. Furthermore, it preferably has an electron affinity Ea of from 1.2 eV to 3.1 eV, more preferably from 1.4 eV to 3.0 eV, and even more preferably from 1.8 eV to 2.8 eV in terms of improvement in durability and decrease in driving voltage.

Specific examples of such hole transporting host material include pyrrole, indole, carbazole, azaindole, azacarbazole, pyrazole, imidazole, polyarylalkane, pyrazoline, pyrazolone, phenylenediamine, arylamine, amino-substituted chalcone, styrylanthracene, fluorenone, hydrazone, stilbene, silazane, aromatic tertiary amine compounds, styrylamine compounds, aromatic dimethylidine compounds, porphyrin compounds, polysilane compounds, poly(N-vinylcarbazole), aniline copolymers, electric conductive high-molecular oligomers such as thiophene oligomers, polythiophenes and the like, organosilanes, carbon films, derivatives thereof, and the like.

Among these, indole derivatives, carbazole derivatives, azaindole derivatives, azacarbazole derivatives, aromatic tertiary amine compounds, and thiophene derivatives are preferable, and particularly, compounds containing a plurality of indole skeletons, carbazole skeletons, azaindole skeletons, azacarbazole skeletons, and/or aromatic tertiary amine skeletons in the molecule are preferred.

As specific examples of the hole transporting host material described above, the following compounds may be listed, but the present invention is not limited thereto.

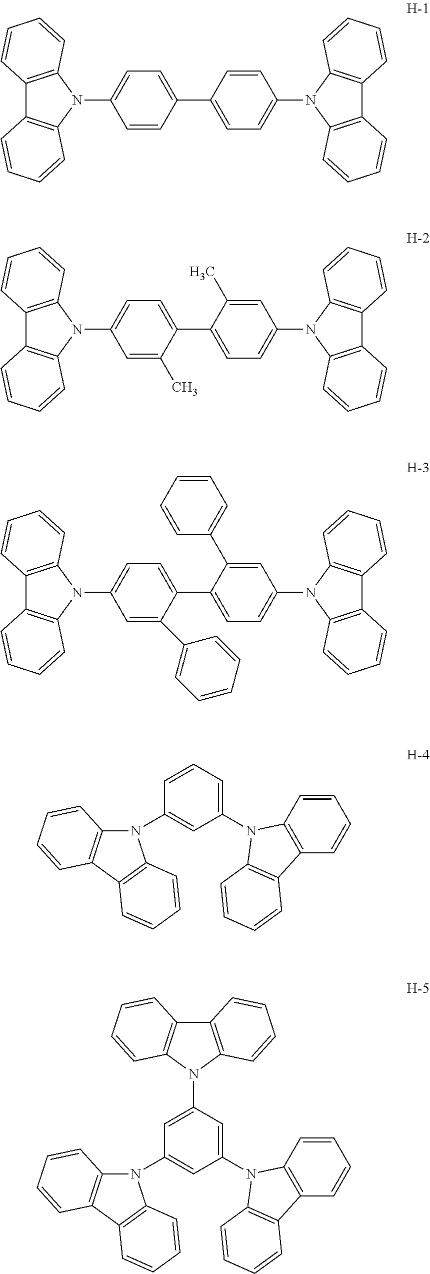

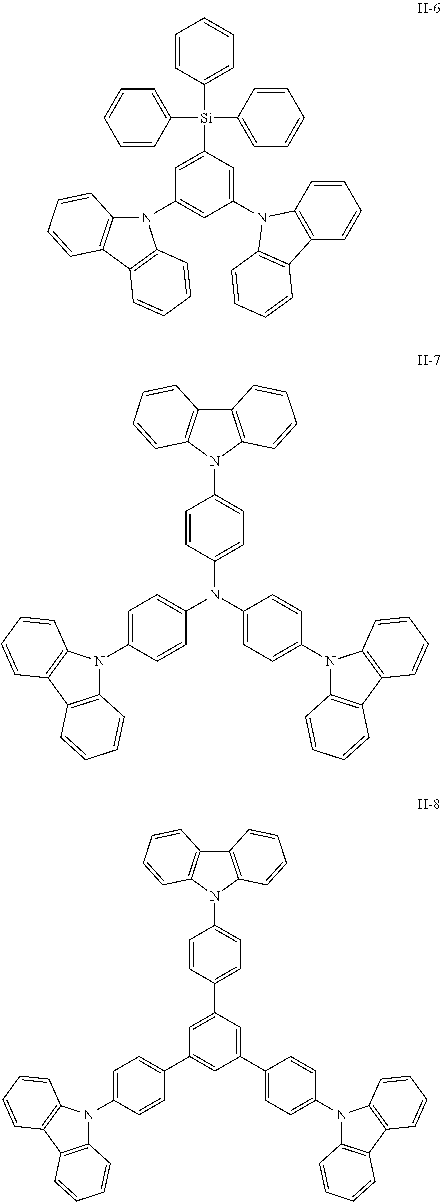

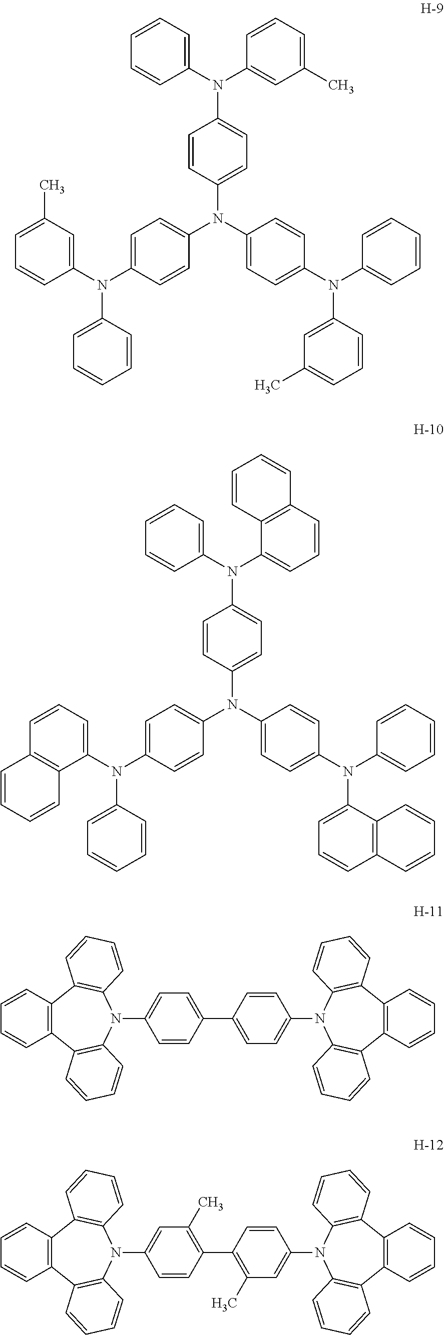

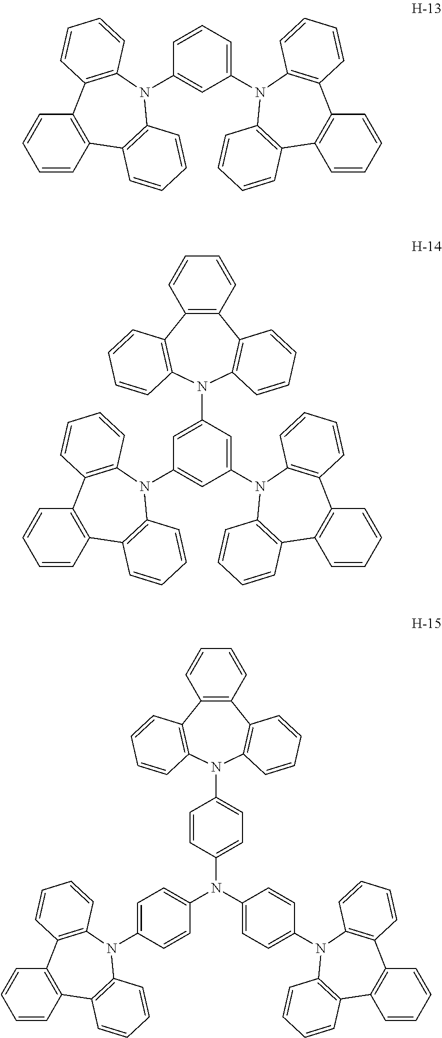

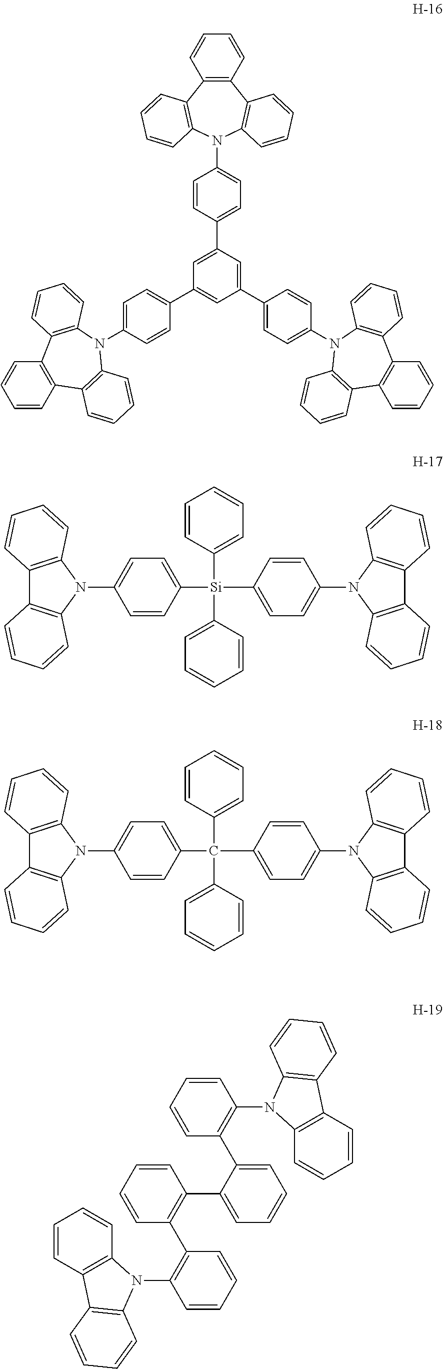

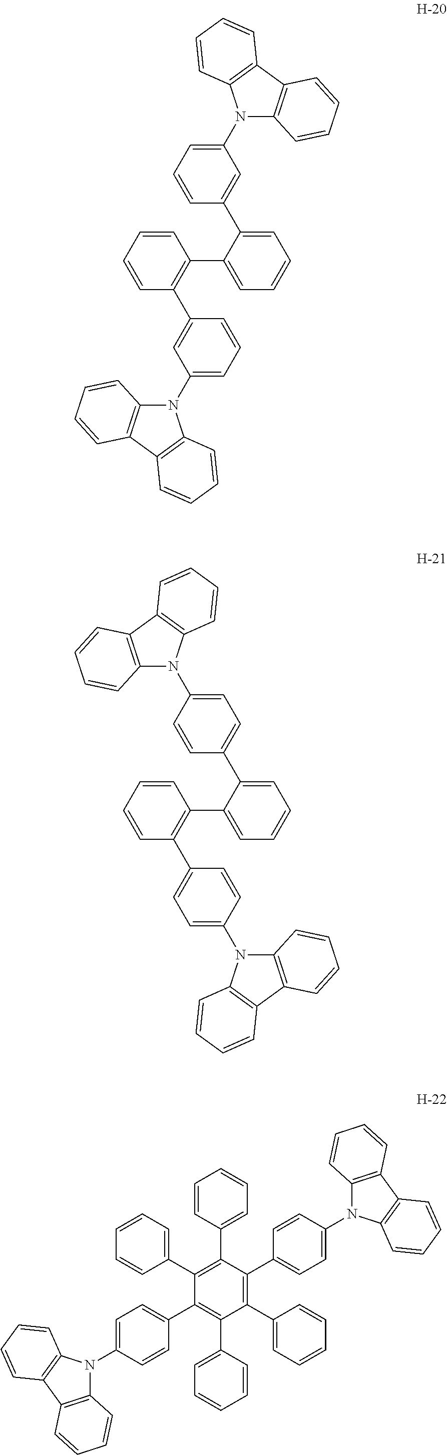

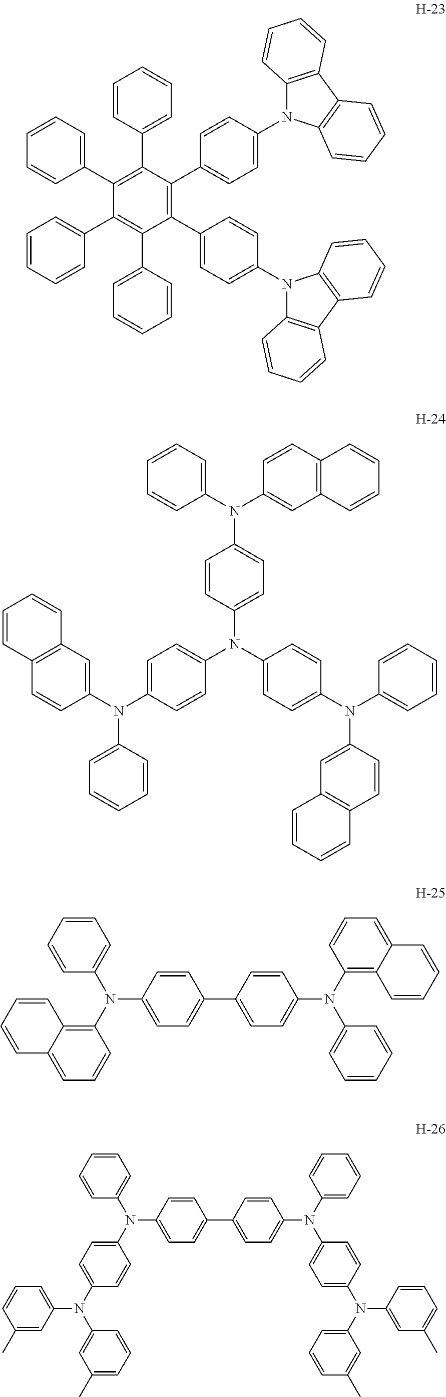

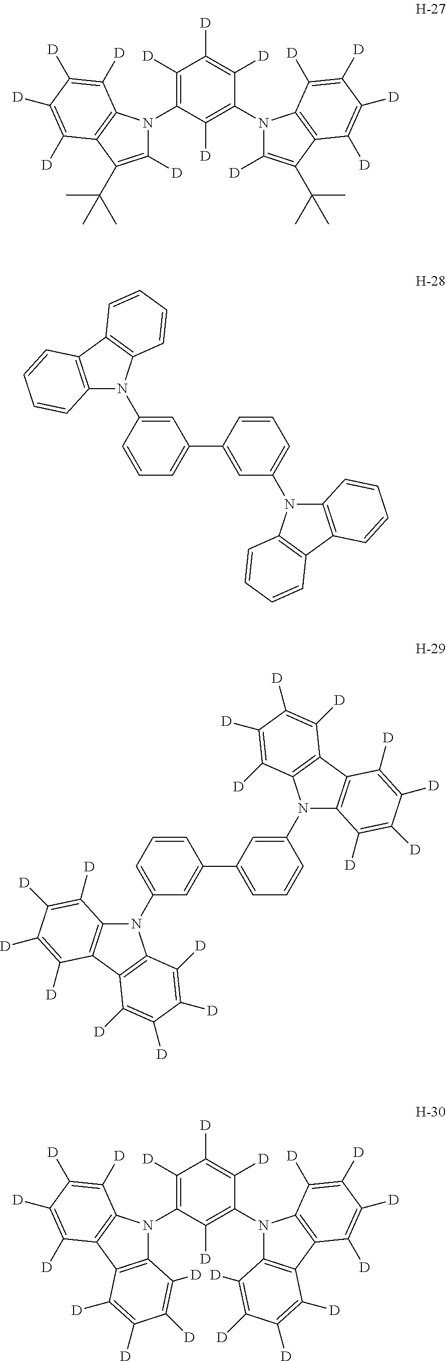

The method of forming a film and a stacked film of the present invention is adoptable to manufacturing of organic electronic devices such as organic EL device. An exemplary configuration of the organic EL device manufacturable by the method of the present invention (referred to as “organic EL device of the present invention”, hereinafter) will be detailed below.

The organic EL device of the present invention has a cathode and an anode on a substrate, and a plurality of organic compound layers, including a luminescent layer, formed between both electrodes. On both sides of the luminescent layer, organic compound layers are formed in adjacent thereto.

An additional organic compound layer may be provided between each electrode and each organic compound layer which resides in adjacent to the luminescent layer.

In view of specific features of luminescent devices, at least either one of the anode and cathode is preferably transparent. In general, the anode is configured to be transparent.

As for a mode of stacking of the organic compound layers in the present invention, it is preferable that the hole transporting layer, the luminescent layer, and the electron transporting layer are stacked in this order, when viewed from the anode side. In addition, a charge blocking layer, for example, may be provided between the hole transporting layer and the luminescent layer, or between the luminescent layer and the electron transporting layer.

One preferable embodiment of the organic compound layers in the organic electroluminescent device of the present invention relates to an embodiment having at least the hole injection layer, the hole transporting layer, the luminescent layer, a hole blocking layer, the electron transporting layer, and the electron injection layer stacked in this order when viewed from the anode side.

In the embodiment having the hole blocking layer between the luminescent layer and the electron transporting layer, the organic compound layer in adjacent to the luminescent layer on the anode side serves as the hole transporting layer, and that on the cathode side serves as the hole blocking layer.

The hole injection layer may be provided between the anode and the hole transporting layer, and the electron injection layer may be provided between the cathode and the electron transporting layer.

Note that each layer may be divided into a plurality of secondary layers.

### <Substrate>

The substrate of the organic EL device is preferably a substrate which does not scatter or attenuate light emitted from the luminescent layer. Materials for composing such substrate may be exemplified by inorganic materials such as yttria stabilized zirconia (YSZ) and glass; and organic materials such as polyester represented by polyethylene terephthalate, polybutylene phthalate and polyethylene naphthalate; polystyrene; polycarbonate; polyethersulfone; polyarylate; polyimide; polycyclolefin; norbornene resin and poly(chlorotrifluoroethylene).

For an exemplary case where glass is used for the substrate, non-alkali glass is preferably used in view of reducing ions possibly eluted from the glass. For another exemplary case where soda-lime glass is used, the substrate preferably has a barrier coating typically composed of silica formed thereon.

The organic material used herein is preferably excellent in the heat resistance, dimensional stability, solvent resistance, electrical insulating property and workability.

Geometry, structure, size and so forth of the substrate are not specifically limited, and may appropriately be selectable depending on applications and purposes.

In general, the geometry of the substrate is preferably a plate. The substrate may have a single-layered structure or a stacked structure, and may be composed of a single component or two or more components.

While the substrate may be colorless-and-transparent, or may be colored-and-transparent, it may more preferably be colorless-and-transparent, in view of avoiding scattering or attenuation of light emitted from the organic luminescent layer.

The substrate may be provided with a moisture impermeable layer (gas barrier layer) on the top surface or the back surface thereof.

Inorganic substances preferably adoptable to materials for composing the moisture impermeable layer (gas barrier layer) include silicon nitride and silicon oxide. The moisture impermeable layer (gas barrier layer) may be formed typically by RF sputtering.

For an exemplary case where the thermoplastic substrate is used, a hard coat layer, an undercoat layer and so forth may be provided if necessary.

### <Anode>

The anode may generally be good enough to function so as to supply holes to the organic compound layer, and is therefore not specifically limited in geometry, structure, size and so forth, while allowing appropriate selection from publicly-known electrode materials corresponding to applications and purposes of luminescent devices.

As described in the above, the anode is generally provided as a transparent electrode.

Preferable materials for composing the anode may be exemplified by metal, alloy, metal oxide, electro-conductive compound, or mixtures of these materials.

Specific examples of the anode material include electro-conductive metal oxides such as antimony- or fluorine-doped tin oxides (ATO, FTO), tin oxide, zinc oxide, indium oxide, indium tin oxide (ITO), and zinc indium oxide (IZO); metals such as gold, silver, chromium and nickel; mixtures or stacked materials of these metals and electro-conductive metal oxides; inorganic electro-conductive substances such as copper iodide, and copper sulfide; organic electro-conductive materials such as polyaniline, polythiophene and polypyrrole; and stacked material of ITO and any of these materials.

Among them, electro-conductive metal oxides are preferable, and ITO is particularly preferable by virtue of its productivity, excellent electro-conductivity, transparency and so forth.

The anode may be formed on the substrate, typically by wet process such as printing and coating; physical process such as vacuum evaporation, sputtering and ion plating; and chemical process such as CVD and plasma-assisted CVD, which may be selected while considering matching with a material composing the anode.

For an exemplary case where ITO is selected as the material for composing the anode, the anode may be formed by DC or RF sputtering, vacuum evaporation, ion plating and so forth.

In the organic electroluminescent device of the present invention, position of formation of the anode is not specifically limited, and may appropriately be selectable corresponding to applications and purposes of the luminescent devices.

In this case, the anode may be formed entirely or partially over one surface of the substrate.

The anode may be patterned by chemical etching combined with photolithography, or by physical etching such as laser etching, or by vacuum evaporation or sputtering through a mask, or by lift-off process or printing.

Thickness of the anode may appropriately be selectable depending on a material for composing the anode, and is generally 10 nm to 50 μm or around, and preferably 50 nm to 20 μm, although not unconditionally specified.

Resistivity of the anode is preferably 10³Ω/□ or smaller, and more preferably 10²Ω/□ or smaller.

For the case where the anode is transparent, it may be colorless or colored.

In view of extracting light through the transparent anode, the anode preferably has a transmissivity of 60% or larger, and more preferably 70% or larger.

The transparent anode is detailed in “Tomei Denkyoku-Maku no Shin-Tenkai (The New Development of Transparent Electrode Film”, compilation and commentaries by Yutaka SAWADA, published by CMC Publishing Co., Ltd. (1999), the contents of which may be incorporated into the present invention.

For the case where a low-heat-resistance plastic base is adopted, the transparent anode may preferably be composed of ITO or IZO, grown at low temperatures not higher than 150° C.

### <Cathode>

The cathode may generally be good enough to function so as to inject electrons into the organic compound layer, and is therefore not specifically limited in geometry, structure, size and so forth, while allowing appropriate selection from publicly-known electrode materials corresponding to applications and purposes of luminescent devices.

Materials for composing the cathode may be exemplified by metal, alloy, metal oxide, electro-conductive compound, and mixtures of these materials.

The specific examples include alkali metals (Li, Na, K, Cs, etc.), alkali earth metals (Mg, Ca, etc.), gold, silver, lead, aluminum, sodium-potassium alloy, lithium-aluminum alloy, magnesium-silver alloy, indium, and rare metals such as ytterbium.

While each of these materials may be used independently, two or more materials may preferably be combined in view of striking a balance between stability and electron injection performance.

Among them, alkali metals and alkali earth metals are preferable as the materials for composing the cathode in view of electron injection performance, whereas materials mainly composed of aluminum are preferable in view of storage stability.

The materials mainly composed of aluminum herein includes pure aluminum, alloys containing aluminum and 0.01% by mass to 10% by mass of alkali metals or alkali earth metals, and mixtures of these materials (lithium-aluminum alloy, magnesium-aluminum alloy, etc.).

The materials for composing the cathode are detailed in Japanese Laid-Open Patent Publication Nos. H02-15595 and H05-121172, all of which are adoptable to the present invention.

The cathode may be formed by publicly-known methods without special limitation.

For example, the cathode may be formed by an appropriate method selected from wet process such as printing and coating; physical process such as vacuum evaporation, sputtering and ion plating; and chemical process such as CVD and plasma-assisted CVD, while considering matching with a material composing the cathode.

For an exemplary case where metal is selected as a material for composing the cathode, a single species, or two or more species thereof are sputtered in a concomitant or sequential manner.

The cathode may be patterned by chemical etching combined with photolithography, or by physical etching such as laser etching, or by vacuum evaporation or sputtering through a mask, or by lift-off process or printing.

In the present invention, position of formation of the cathode is not specifically limited, and may be formed entirely or partially over the organic compound layer.

Alternatively, a dielectric layer composed of fluoride or oxide of alkali metal or alkali earth metal, having a thickness of 0.1 nm to 5 nm, may be inserted between the cathode and the organic compound layer. The dielectric layer may be understood as a sort of electron injection layer.

The dielectric layer may be formed typically by vacuum evaporation, sputtering, ion plating and so forth.

Thickness of the cathode may appropriately be selectable depending on a material for composing the cathode, and is generally 10 nm to 5 μm or around, and preferably 50 nm to 1 μm, although not unconditionally specified.

The cathode may be transparent, or may be opaque.

The transparent cathode may be formed by forming a material for composing the cathode to as thin as 1 nm to 10 nm, and further by stacking thereon a layer of transparent electro-conductive material such as ITO, IZO and so forth.

### <Organic Compound Layer>

The organic compound layer in the present invention will be explained.

The organic EL device of the present invention has at least one organic compound layer including a luminescent layer, wherein the layers other than the luminescent layer may be exemplified by hole transporting layer, electron transporting layer, charge blocking layer, hole injection layer, electron injection layer and so forth. Among these organic compound layers, one or more layers may be formed by the method of the present invention.

### —Formation of Organic Compound Layer—

In the organic electroluminescent device of the present invention, the individual layers composing the organic compound layer may preferably be formed by any of dry process such as vacuum evaporation and sputtering, wet coating, transfer process, printing, ink-jet printing, apart from using the apparatus of the present invention. The layer is preferably formed by the method of the present invention.

### —Hole Injection Layer, Hole Transporting Layer—

The hole injection layer and the hole transporting layer function to transporting therethrough holes received from the anode or any layer on the anode side towards the cathode side. The layer is preferably formed by the method of the present invention.

Materials adoptable to the hole injection layer and the hole transporting layer of the present invention may be low-molecular-weight compound or polymer compound, without special limitation.

More specifically, the layers preferably contain pyrrole derivative, carbazole derivative, imidazole derivative, polyarylalkane derivative, pyrazoline derivative, pyrazolone derivative, phenylenediamine derivative, arylamine derivative, amino-substituted chalcone derivative, styrylanthracene derivative, fluorenone derivative, hydrazone derivative, stilbene derivative, silazane derivative, aromatic tertiary amine compound, styrylamine compound, aromatic dimethylidene compound, phthalocyanine compound, porphyrine compound, thiophene derivative, organosilane derivative, carbon, phenylazol, metal complex having phenylazine as the ligands thereof, or the like.

The hole injection layer or the hole transporting layer of the organic EL device of the present invention may be introduced with an electron-acceptable dopant.

The electron-acceptable dopant to be introduced into the hole injection layer or the hole transporting layer may be inorganic compound or may be organic compound, so far as they are electron-acceptable and are capable of oxidizing the organic compound.

More specifically, the inorganic compound may be exemplified by metal halides such as ferric chloride, aluminum chloride, gallium chloride, indium chloride and antimony pentachloride; and metal oxides such as vanadium pentoxide and molybdenum trioxide.

The organic compound preferably adoptable herein include compound having nitro group, halogen atom, cyano group, trifluoromethyl group and so forth as substituent, quinone compound, acid anhydride and fullerene.

Besides them, compounds described in Japanese Laid-Open Patent Publication Nos. H06-212153, H11-111463, H11-251067, 2000-196140, 2000-286054, 2000-315580, 2001-102175, 2001-160493, 2002-252085, 2002-56985, 2003-157981, 2003-217862, 2003-229278, 2004-342614, 2005-72012, 2005-166637 and 2005-209643 may preferably be used.

Each of the electron-acceptable dopants may be used independently, or two or more species may be used in combination.

While amount of use of the electron-acceptable dopant may vary depending on species of the material, it is preferably 0.01% by mass to 50% by mass, more preferably 0.05% by mass to 20% by mass, and still more preferably 0.1% by mass to 10% by mass, of the material for composing the hole transporting layer.

Thickness of each of the hole injection layer and the hole transporting layer is preferably 500 nm or smaller, in view of reducing the operational voltage.

Thickness of the hole transporting layer is preferably 1 nm to 500 nm, more preferably 5 nm to 300 nm, and still more preferably 10 nm to 200 nm.

Thickness of the hole injection layer is preferably 0.1 nm to 500 nm, more preferably 0.5 nm to 300 nm, and still more preferably 1 nm to 200 nm.

Each of the hole injection layer and the hole transporting layer may have a single-layered structure composed of a single species or two or more species of the above-descried materials, or may have a multi-layered structure composed of a plurality of layers having the same or different compositions.

### —Electron Injection Layer, Electron Transporting Layer—

The electron injection layer and the electron transporting layer function to transporting therethrough electrons received from the cathode or any layer on the cathode side towards the anode side. The layers are preferably formed by the method of the present invention.

Materials adoptable to the electron injection layer and the electron transporting layer of the present invention may be low-molecular-weight compound or polymer compound, without special limitation.

More specifically, the layers preferably contain pyridine derivative, quinoline derivative, pyrimidine derivative, pyrazine derivative, phthalazine derivative, phenanthroline derivative, triazine derivative, triazole derivative, oxazole derivative, oxadiazole derivative, imidazole derivative, fluorenone derivative, anthraquinodimethane derivative, anthrone derivative, diphenylquinone derivative, thiopyrane dioxide derivative, carbodiimide derivative, fluorenylidene methane derivative, distyrylpyrazine derivative, naphthalene, perylene, armatic tetracarboxylic acid anhydride, phthalocyanine derivative, metal complex of 8-quinolinol derivative and metal phthalocyanine, various metal complexes represented by those having benzoxazole or benzothiazole as ligands, and organic silane derivative represented by silole.

The electron injection layer or the electron transporting layer of the organic EL device of the present invention may be introduced with an electron-donating dopant.

The electron-donating dopant to be introduced into the electron injection layer or the electron transporting layer may be good enough to be electron-donating and capable of reducing the organic compound, and preferable examples adoptable thereto include alkali metals such as Li, alkali earth metals such as Mg, transition metals including rare metals, and reductive organic compounds.

The metal particularly preferably adoptable herein include those having a work function of 4.2 eV or smaller, and specifically exemplified by Li, Na, K, Be, Mg, Ca, Sr, Ba, Y, Cs, La, Sm, Gd and Yb.

The reductive organic compounds may be exemplified by nitrogen-containing compounds, sulfur-containing compounds, and phosphorus-containing compounds.

Besides them, materials described in Japanese Laid-Open Patent Publication Nos. H06-212153, 2000-196140, 2003-68468, 2003-229278 and 2004-342614 may be adoptable.

Each of the electron-donating dopants may be used independently, or two or more species may be used in combination.

While amount of use of the electron-donating dopant may vary depending on species of the material, it is preferably 0.1% by mass to 30% by mass, more preferably 0.1% by mass to 20% by mass, and still more preferably 0.1% by mass to 10% by mass of the electron transporting layer.

Thickness of each of the electron injection layer and the electron transporting layer is preferably 300 nm or smaller, in view of reducing the operational voltage.

Thickness of the electron transporting layer is preferably 1 nm to 500 nm, more preferably 5 nm to 200 nm, and still more preferably 10 nm to 100 nm.

On the other hand, thickness of the electron injection layer is preferably 0.1 nm to 200 nm, more preferably 0.2 nm to 100 nm, and still more preferably 0.5 nm to 50 nm.

Each of the electron injection layer and the electron transporting layer may have a single-layered structure composed of a single species or two or more species of the above-descried materials, or may have a multi-layered structure composed of a plurality of layers having the same or different compositions.

### —Hole Blocking Layer—

The hole blocking layer functions to prevent holes, which are transported from the anode side to the luminescent layer, from penetrating therethrough to reach the cathode side. The layer is preferably formed by the method of the present invention.

In the present invention, the hole blocking layer may be provided as an organic compound layer which lies in adjacent to the luminescent layer on the cathode side.

Compounds for composing the hole blocking layer may be exemplified by aluminum complex such as BAlq, triazole derivative, and phenanthroline derivative such as BCP.

Thickness of the hole blocking layer is preferably 1 nm to 500 nm, more preferably 5 nm to 200 nm, and still more preferably 10 nm to 100 nm.

The hole blocking layer may have a single-layered structure composed of a single species or two or more species of the above-descried materials, or may have a multi-layered structure composed of a plurality of layers having the same or different compositions.

### —Electron Blocking Layer—

The electron blocking layer functions to prevent electrons, which are transported from the cathode side to the luminescent layer, from penetrating therethrough to reach the anode side. The layer is preferably formed by the method of the present invention.

In the present invention, the electron blocking layer may be provided as an organic compound layer which lies in adjacent to the luminescent layer on the anode side.

The compounds enumerated in the above as the hole transporting materials may be adoptable to compounds for composing the electron blocking layer.

Thickness of the electron blocking layer is preferably 1 nm to 500 nm, more preferably 5 nm to 200 nm, and still more preferably 10 nm to 100 nm.

The electron blocking layer may have a single-layered structure composed of a single species or two or more species of the above-descried materials, or may have a multi-layered structure composed of a plurality of layers having the same or different compositions.

### <Protective Layer>

In the present invention, the entire portion of the organic EL device may be protected by a protective layer.

Materials contained in the protective layer may be good enough to prevent any substances which possibly accelerate degradation of device, such as water and oxygen, from entering the device.

The specific examples of the materials may be exemplified by metals such as In, Sn, Pb, Au, Cu, Ag, Al, Ti and Ni, metal oxides such as MgO, SiO, SiC₂, Al₂C₃, GeO, NiO, CaO, BaO, Fe₂O₃, Y₂O₃ and TiO₂, metal nitrides such as SiNₓ and SiNₓO_{y}, metal fluorides such as MgF₂, LiF, AlF₃ and CaF₂, polyethylene, polypropylene, polymethyl methacrylate, polyimide, polyurea, polytetrafluoroethylene, poly(chlorotrifluoroethylene), poly(dichlorodifluoroethylene), copolymer of chlorotrifluoroethylene and dichlorodifluoroethylene, copolymer obtained by copolymerizing a monomer mixture containing tetrafluoroethylene and at least one species of comonomer, fluorine-containing copolymer having a cyclic structure in the principal chain thereof, water absorbent having a water absorption ratio of 1% or larger, and moisture-proof substance having a water absorption ratio of 0.1% or smaller.

Methods of forming the protective layer adoptable herein include vacuum evaporation, sputtering, reactive sputtering, MBE (molecular beam epitaxy), cluster ion beam-assisted deposition, ion plating, plasma-assisted polymerization (RF-excited ion plating), plasma-enhanced CVD, laser-assisted CVD, thermal CVD, gas source CVD, coating, printing and transfer printing, without special limitation. Of course, the protective layer may be formed by the method of the present invention.

### <Encapsulation>

The organic electroluminescent device of the present invention may be encapsulated as a whole, using an encapsulation package.

A space between the encapsulation package and the luminescent device may be filled with a moisture absorbent or inert liquid.

The moisture absorbent may be exemplified by barium oxide, sodium oxide, potassium oxide, calcium oxide, sodium sulfate, calcium sulfate, magnesium sulfate, phosphorus pentoxide, calcium chloride, magnesium chloride, copper chloride, cesium fluoride, niobium fluoride, calcium bromide, vanadium bromide, Molecular Sieve, zeolite, and magnesium oxide, without special limitation.

The inert liquid may be exemplified by paraffins, liquid paraffins, fluorine-containing solvents such as perfluoroalkane, perfluoroamine and perfluoroether, chlorine-containing solvent and silicone oils, without special limitation.

### <Operation>

The organic electroluminescent device of the present invention emits light, when applied with a DC voltage (AC component may be contained if necessary) of 2 V to 15 V, in general, between the anode and the cathode.

Methods of operating the organic electroluminescent device of the present invention adoptable herein includes those described in Japanese Laid-Open Patent Publication Nos. H02-148687, H06-301355, H05-29080, H07-134558, H08-234685 and H08-241047, Japanese Patent Publication No. 2784615, U.S. Pat. Nos. 5,828,429 and 6,023,308.

The luminescent device of the present invention may be improved in the light extraction efficiency, by various publicly-known strategies.

The light extraction efficiency may be improved and thereby the external quantum efficiency may be improved, typically by modifying the surface profile of the substrate (formation of a fine irregularity pattern), controlling refractive indices of the substrate, the ITO layer and the organic layers, or by adjusting the thickness of the substrate, the ITO layer and the organic layers.

The luminescent device of the present invention may be the one of so-called top emission type by which light is extracted from the anode side.

While the description in the above dealt with the configuration of the organic electroluminescent device, the method of the present invention is, of course, applicable also to formation of films used for organic solar cell, organic field effect transistor and so forth. Still alternatively, the present invention is applicable to method of forming a film used for a variety of optical components such as reflective plate and polarizer plate.

### Examples

Paragraphs below will further specifically describe features of the present invention, referring to Examples and Comparative Examples. Any materials, amount of use, ratio, details of processing, procedures of processing and so forth shown in Examples may appropriately be modified without departing from the spirit of the present invention. Therefore, it is to be understood that the scope of the present invention should not be interpreted in a limited manner based on the specific examples shown below.

Using an apparatus similar to the spray-type film forming apparatus illustrated in FIG. 1, a spray liquid was sprayed through a dual fluid nozzle 12 to produce liquid droplets, the liquid droplets were concentrated in a chamber 14, and the concentrated liquid droplets were deposited on a substrate 22 to obtain a thin film. The temperature of the inner space of the chamber 14 was controlled by temperature of water passing through a flow path provided around the chamber 14.

The substrate used herein was made of ITO glass (from Aldrich, 30 to 60Ω/□), washed by ultrasonic cleaning sequentially in neutral detergent and water for approximately 5 minutes each, blown by a nitrogen blower so as to remove the residual water remaining thereon, and then heated to dry. A 1%-by-mass solution of PTPDES-2 having a structure illustrated below, dissolved in cyclohexanone, was spin-coated at 2000 rpm to form a 50-nm-thick film, to thereby complete the substrate. The PTPDES-2 film, soluble to THF, functions as a hole transporting layer.

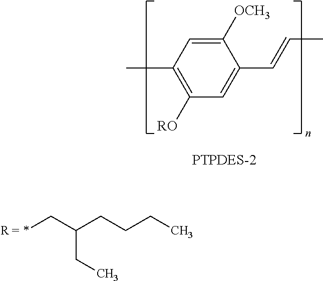

Next, the glass substrate was set on a substrate holder 24 of the apparatus illustrated in FIG. 1. The temperature in the inner space of the chamber 14 was controlled by setting the temperature of water allowed to pass through the flow path around the chamber 14 at the level shown below, and by setting temperature of water allowed to pass through the substrate holder 24 at 50° C. An opening of the chamber 14 was adjusted to 10 mm in diameter, and distance between the opening and the substrate 22 was adjusted to 10 mm.

The spray liquid adopted herein was a THF solution of poly[2-methoxy-5-(2-ethylhexyloxy)-1,4-phenylenevinylene] (MEH-PPV) illustrated below. Concentration of the spray liquids used in individual Examples and Comparative Examples were listed in Table 1.

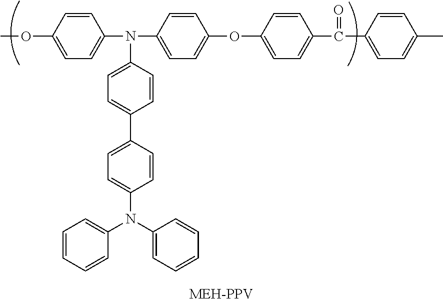

The spray liquid supplied from the syringe pump 16 and nitrogen gas whose pressure was controlled by the regulator 18 were respectively pumped to the dual fluid nozzle 12, and the spray liquid was sprayed to produce the liquid droplets. In order to adjust the liquid droplets to a desired diameter, flow rate of the spray liquid was adjusted in the range from 0 to 10 mL/min, and flow rate of gas was adjusted in the range from 0 to 10 L/min. The dual fluid nozzle 12 adopted herein was AM-6 from Atomax Co., Ltd., the syringe pump 16 for adjusting the flow rate of the spray liquid was a product from Harvard Apparatus, and the regulator 18 for adjusting the flow rate gas was a product from Atomax Co., Ltd. Concentration of solvent gas in the chamber 14 was adjusted to 20% LEL or below so as to balance the intake and exhaust, from an explosion-proof viewpoint.

The organic films were formed according to various conditions listed in Table below.

In Example 1, the spray liquid having a solid content concentration of 0.01% by mass was sprayed over the first 2.5 minutes after the start of process, and the spray liquid having a solid content concentration of 0.001% by mass was then sprayed under the same conditions over the next 2.5 minutes. Also conditions of heating in the chamber were set to the same. Accordingly, the difference in the levels of solid content concentration of the spray liquids employed herein was reflected in the solid content concentration of the liquid droplets at the time of arriving at the substrate, as practically demonstrated such that ratio of the levels of solid content concentration of the liquid droplets at the time of arriving at the substrate over the first 2.5-minute period and the second 2.5-minute period was found to be approximately 10:1.

In Example 2, the spray liquid having a solid content concentration of 0.01% by mass was sprayed for the first 1.5 minutes, and the spray liquid having a solid content concentration of 0.005% by mass was sprayed under the same conditions over the next 1.5 minutes, and the spray liquid having a solid content concentration of 0.001% by mass was sprayed under the same conditions over the last 1.5 minutes. Also conditions of heating in the chamber were set to the same. Accordingly, the difference in the levels of solid content concentration of the spray liquids employed herein was reflected in the solid content concentration of the liquid droplets at the time of arriving at the substrate, as practically demonstrated such that ratio of the solid content concentrations of the liquid droplets at the time of arriving at the substrate over the first 1.5-minute period, the next 1.5-minute period and the last 1.5-minute period was found to be approximately 10:5:1.

In Example 3, the same spray liquid was used throughout the process, but the temperature of the chamber was set to 50° C. for the first 2.5 minutes after the start of process, and then set to 25° C. for the next 2.5 minutes. As a result of change in the temperature inside the chamber, the degree of condensation of the liquid droplets varied between the first 2.5 minutes and the second 2.5 minutes, and thereby the solid content concentration of the liquid droplets at the time of arriving at the substrate was found to be higher in the first half, and lower in the second half.

In Example 4, the same spray liquid was used throughout the process, but a condition of spraying was varied so as to produce 3-μm liquid droplets through the nozzle for the first 2.5 minutes, and so as to produce 5-μm liquid droplets for the next 2.5 minutes. Conditions of heating in the chamber were set to the same. Accordingly, the difference in the diameter of the liquid droplets as sprayed from the nozzle was reflected in the size of the liquid droplets at the time of arriving at the substrate, or the solid content concentration, as practically demonstrated such that the solid content concentrations of the liquid droplets at the time of arriving at the substrate was found to be higher in the first half, and lower in the second half.

In Comparative Examples 1 to 6, all conditions were not varied throughout the period from the start to the end, so that the solid content concentration of the liquid droplets at the time of arriving at the substrate was found to be almost constant.

Surface smoothness of the individual films thus formed, and dissolution of the underlying PTPDES-2 film were evaluated.

The surface smoothness of the thus-formed films was evaluated based on values of surface roughness Ra measured using a contact-type roughness analyzer.

Dissolution of the underlying layer was judged based on cross-sectional SEM/TEM image, and element analysis in the thickness-wise direction on the cross-sectional TEM image, particularly by confirming presence of nitrogen, where criteria of judgment are:

“dissolved” for a mixed layer found entirely over the film, while an interface not confirmed;

“partially dissolved” for an interface partially confirmed, with a several-nanometer-thick mixed layer; and “not dissolved” for an interface confirmed, while a mixed layer not found.

Adhesiveness of the film was judged based on tape peeling test, where criteria of judgment are:

“∘” for no peeling;

“Δ” for partial peeling; and

“x” for peeling over the entire surface.

External quantum efficiency was calculated based on luminous intensity observed when the films, formed under the conditions listed below and then further stacked with LiF and Al films by vacuum evaporation, were brought into luminescent state under applied electric field.

Results are shown in Table below.

TABLE 1

| | Conditions | | | | | | | | |
|---|---|---|---|---|---|---|---|---|---|
| | | | Liquid | | | Evaluation | | | |
| | | Concen- | droplet | Temperature | | Surface- | | Adhesiveness | External |
| | | tration of | diameter | in chamber | Spray | rough- | Dissolu- | between | quantum |
| | Number of | spray liquid | *1 (SMD) | Degrees | time | ness Ra | tion of | upper and | efficiency |
| | nozzles | % by mass | μm | Celsius | min. | nm | lower film | lower layers | % |
| Comparative | 1 | 0.001 | 5 | 25 | 5 | 8 | dissolved | — | 0.3 |
| Example 1 | | | | | | | | (mixed layer | |
| | | | | | | | | formed) | |
| Comparative | 1 | 0.01 | 5 | 25 | 5 | 40 | not | x | 0.1 |
| Example 2 | | | | | | | dissolved | | |
| Example 1 | 2 | 0.01→0.001 | 5 | 25 | 2.5→2.5 | 12 | partially | Δ | 1.3 |
| | | | | | | | dissolved | | |
| Example 2 | 3 | 0.01→ | 5 | 25 | 1.5→ | 10 | partially | Δ | 1.5 |
| | | 0.005→0.001 | | | 1.5→1.5 | | dissolved | | |
| Comparative | 1 | 0.001 | 5 | 50 | 5 | 21 | not | x | 0.1 |
| Example 3 | | | | | | | dissolved | | |
| Comparative | 1 | 0.001 | 5 | 15 | 5 | 6 | dissolved | — | 0.2 |
| Example 4 | | | | | | | | (mixed layer | |
| | | | | | | | | formed) | |
| Example 3 | 1 | 0.001 | 5 | 50→25 | 2.5→2.5 | 9 | partially | Δ | 1.2 |
| | | | | | | | dissolved | | |
| Comparative | 1 | 0.001 | 3 | 25 | 5 | 18 | not | x | 0.2 |
| Example 5 | | | | | | | dissolved | | |
| Comparative | 1 | 0.001 | 8 | 25 | 5 | 10 | dissolved | — | 0.2 |
| Example 6 | | | | | | | | (mixed layer | |
| | | | | | | | | formed) | |
| Example 4 | 2 | 0.001 | 3→5 | 25 | 2.5→2.5 | 10 | partially | Δ | 1.0 |
| | | | | | | | dissolved | | |

*1: diameter of liquid droplets as sprayed from the nozzle.

It is understood from the results in the above that all Comparative Examples failed in achieving a balance between the avoidance of dissolution of the lower film and excellent surface smoothness, leaving the problems in the conventional wet process unsolved. On the contrary, it is understood that the thin films of Examples were excellent surface smoothness without dissolving the lower film, while successfully solving the problems in the conventional wet process. It is also confirmed that the partial dissolution of the lower film resulted in improvement of adhesiveness and external quantum efficiency.

1. A method of forming a thin film comprising:
spraying a spray liquid prepared by dissolving and/or dispersing a solute in a solvent to form liquid droplets;
concentrating the liquid droplets by vaporizing the solvent contained therein; and
depositing the concentrated liquid droplets on a substrate or a layer formed on the substrate,
wherein liquid droplets having solid content concentration C₂ are deposited after liquid droplets having solid content concentration C₁ are deposited, provided that C₁>C₂ is satisfied.

2. The method of claim 1, wherein the liquid droplets to be deposited contain at least one species of solvent capable of dissolving at least one material composing the substrate or the layer formed on the substrate.

3. The method of claim 1, wherein the liquid droplets having solid content concentration C₁ and the liquid droplets having solid content concentration C₂ have the same solid content formulation.

4. The method of claim 1, wherein three or more species of liquid droplets differing in the solid content concentration from each other are deposited sequentially in the order of the solid content concentration from the higher to the lower.

5. The method of claim 1, wherein the liquid droplets having solid content concentration C₂ are deposited with a liquid droplet diameter D₂ after the liquid droplets having solid content concentration C₁ are deposited with a liquid droplet diameter D₁, provided that C₁>C₂ and D₁<D₂ are satisfied.

6. The method of claim 1, wherein, after the liquid droplets having solid content concentration C₁ are deposited, the solid content concentration of the liquid droplets to be disposed is varied from C₁ to C₂ by adjusting concentration of the spray liquid pumped to a nozzle.

7. The method of claim 6, wherein two or more nozzles are used, and the solid content concentration of the liquid droplets to be disposed is varied from C₁ to C₂ by spraying two or more spray liquids, differing in solid content concentration from each other, from the two or more nozzles respectively according to time control.

8. The method of claim 1, wherein the solid content concentration of the liquid droplets to be disposed is varied from C₁ to C₂ by adjusting concentrating conditions of the liquid droplets.

9. The method of claim 8, wherein the solid content concentration of the liquid droplets to be disposed is varied from C₁ to C₂ by adjusting a temperature of an atmosphere, through which the liquid droplets pass from spraying to depositing on the substrate or the layer formed on the substrate, according to the time.

10. The method of claim 1, wherein the solid content concentration of the liquid droplets to be disposed is varied from C₁ to C₂ by adjusting a liquid droplet diameter at the time of spraying.

11. The method of claim 1, wherein the spray liquid contains at least one species selected from organic semiconductor, organic luminescent material, organic electron transfer material, and organic hole transfer material.

12. The method of claim 1, to be used for forming any one of organic semiconductor layer, luminescent layer, electron transporting layer, electron injection layer, hole transporting layer, and hole injection layer.

13. A method of forming a stacked film comprising at least:
forming a lower single-layered film having a homogenous solid content formulation, according to a method of claim 1; and
forming, on the lower single-layered film, an upper single-layered film having a solid content formulation partially or wholly different from that of the lower single-layered film, according to a method of claim 1.

14. A stacked film formed according to a method described in claim 1, having a zone where the lower layer and the upper layer mix with each other, the thickness of the zone being equal to or less than 10 nm.

15. A stacked film formed according to a method described in claim 13, having a zone where the lower layer and the upper layer mix with each other, the thickness of the zone being equal to or less than 10 nm.
